(19) United States
(12) Patent Application Publication
(10) Pub. No.: US 2026/0026281 A1
(43) Pub. Date: Jan. 22, 2026

(54) METHOD FOR MANUFACTURING SEMICONDUCTOR SUBSTRATE AND UNDERLAYER FILM-FORMING COMPOSITION

(71) Applicant: JSR CORPORATION, Tokyo (JP)

(72) Inventors: Kazuya TAKADA, Tokyo (JP); Ayaka SUZUKI, Tokyo (JP); Akitaka NII, Tokyo (JP); Tatsuya KASAI, Tokyo (JP)

(73) Assignee: JSR CORPORATION, Tokyo (JP)

(21) Appl. No.: 19/339,423

(22) Filed: Sep. 25, 2025

Related U.S. Application Data
(63) Continuation-in-part of application No. PCT/JP2024/010059, filed on Mar. 14, 2024.

(30) Foreign Application Priority Data
Mar. 31, 2023 (JP) 2023-057628

(51) Int. Cl. H01L 21/308; G03F 7/004; G03F 7/075; H01L 21/027

(52) U.S. Cl. CPC H01L 21/3081; G03F 7/0048; G03F 7/075; H01L 21/0275; H01L 21/3086

(57) ABSTRACT

A method for manufacturing a semiconductor substrate, includes: applying an underlayer film-forming composition directly or indirectly to a substrate to form an underlayer film; applying a composition for forming a metal-containing resist film to the underlayer film to form a metal-containing resist film; exposing the metal-containing resist film to extreme ultraviolet rays; and developing the exposed metal-containing resist film. The underlayer film-forming composition includes: a compound including at least one structural unit selected from the group consisting of a structural unit (α-1) represented by formula (1-1) and a structural unit (α-2) represented by formula (1-2). X is a monovalent aliphatic hydrocarbon group having 1 to 20 carbon atoms or a monovalent aliphatic hydrocarbon group having 1 to 20 carbon atoms substituted with at least one halogen atom. Y is a monovalent organic group having 1 to 20 carbon atoms, a hydroxy group, or a halogen atom.

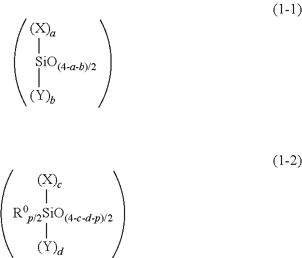

### CROSS-REFERENCE TO RELATED APPLICATIONS

The present application is a continuation-in-part application of International Patent Application No. PCT/JP2024/010059 filed Mar. 14, 2024, which claims priority to Japanese Patent Application No. 2023-057628 filed Mar. 31, 2023. The contents of these applications are incorporated herein by reference in their entirety.

### BACKGROUND OF THE DISCLOSURE

### Technical Field

The present disclosure relates to a method for manufacturing a semiconductor substrate and an underlayer film-forming composition.

### Background Art

For pattern formation in the manufacture of semiconductor substrates, for example, a multilayer resist process or the like is used in which a patterned substrate is formed by etching using, as a mask, a resist pattern obtained by exposing and developing a resist film laminated on a substrate via an organic underlayer film, a silicon-containing film, and the like (WO2022/260154).

### SUMMARY

According to an aspect of the present disclosure, a method for manufacturing a semiconductor substrate, includes: applying an underlayer film-forming composition (hereinafter, also referred to as a “composition”) directly or indirectly to a substrate to form an underlayer film; applying a composition for forming a metal-containing resist film to the underlayer film to form a metal-containing resist film; exposing the metal-containing resist film to extreme ultraviolet rays; and developing the exposed metal-containing resist film. The underlayer film-forming composition includes: a compound (also referred to as “compound [A]”) including at least one structural unit (also referred to as “structural unit (α)”) selected from the group consisting of a structural unit (α-1) represented by formula (1-1) and a structural unit (α-2) represented by formula (1-2); and a solvent (also referred to as “solvent [B]”). A total content ratio of the structural unit (α-1) and the structural unit (α-2) to all structural units constituting the compound is 50 mol % or more and 100 mol % or less.

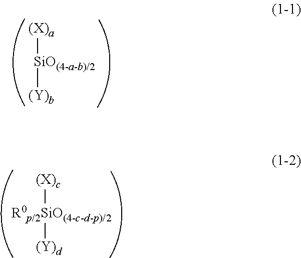

In the formula (1-1), X is a monovalent aliphatic hydrocarbon group having 1 to 20 carbon atoms or a monovalent aliphatic hydrocarbon group having 1 to 20 carbon atoms substituted with at least one halogen atom; a is an integer of 1 to 3; when a is 2 or more, the plurality of Xs are the same or different from each other; Y is a monovalent organic group having 1 to 20 carbon atoms, a hydroxy group, or a halogen atom; b is an integer of 0 to 2; when b is 2, two Ys are the same or different from each other; and a+b is 3 or less. In the formula (1-2), X is a monovalent aliphatic hydrocarbon group having 1 to 20 carbon atoms or a monovalent aliphatic hydrocarbon group having 1 to 20 carbon atoms substituted with at least one halogen atom; c is an integer of 1 to 3; when c is 2 or more, the plurality of Xs are the same or different from each other; Y is a monovalent organic group having 1 to 20 carbon atoms, a hydroxy group, or a halogen atom; d is an integer of 0 to 2; when d is 2, two Ys are the same or different from each other; R⁰ is a substituted or unsubstituted divalent hydrocarbon group that has 1 to 20 carbon atoms and is bonded to two silicon atoms; p is an integer of 1 to 3; when p is 2 or more, the plurality of Ros are the same or different from each other; and c+d+p is 4 or less.

According to another aspect of the present disclosure, an underlayer film-forming composition, includes: a compound including at least one structural unit selected from the group consisting of a structural unit (α-1) represented by formula (1-1) and a structural unit (α-2) represented by formula (1-2); and a solvent. A total content ratio of the structural unit (α-1) and the structural unit (α-2) to all structural units constituting the compound is 50 mol % or more and 100 mol % or less:

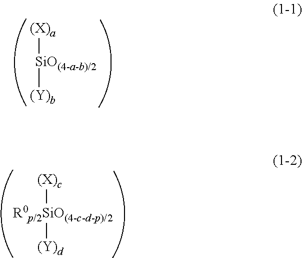

In the formula (1-1), X is a monovalent aliphatic hydrocarbon group having 1 to 20 carbon atoms or a monovalent aliphatic hydrocarbon group having 1 to 20 carbon atoms substituted with at least one halogen atom; a is an integer of 1 to 3; when a is 2 or more, the plurality of Xs are the same or different from each other; Y is a monovalent organic group having 1 to 20 carbon atoms, a hydroxy group, or a halogen atom; b is an integer of 0 to 2; when b is 2, two Ys are the same or different from each other; and a+b is 3 or less. In the formula (1-2), X is a monovalent aliphatic hydrocarbon group having 1 to 20 carbon atoms or a monovalent aliphatic hydrocarbon group having 1 to 20 carbon atoms substituted with at least one halogen atom; c is an integer of 1 to 3; when c is 2 or more, the plurality of Xs are the same or different from each other; Y is a monovalent organic group having 1 to 20 carbon atoms, a hydroxy group, or a halogen atom; d is an integer of 0 to 2; when d is 2, two Ys are the same or different from each other; R⁰ is a substituted or unsubstituted divalent hydrocarbon group that has 1 to 20 carbon atoms and is bonded to two silicon atoms; p is an integer of 1 to 3; when p is 2 or more, the plurality of Ros are the same or different from each other; and c+d+p is 4 or less.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In recent years, highly enhanced integration of semiconductor devices has further advanced, and exposure light to be used tends to have a shorter wavelength, as from a KrF excimer laser beam (248 nm) or an ArF excimer laser beam (193 nm) to an extreme ultraviolet ray (13.5 nm; hereinafter also referred to as “EUV”). Accordingly, a metal-containing resist film is being used instead of the organic resist film.

While the line width of a resist pattern formed through exposure to extreme ultraviolet rays and development is being miniaturized, an underlayer film for a metal-containing resist is required to have pattern rectangularity of securing rectangularity of a resist pattern by suppressing trailing of the pattern at the bottom of a resist film and development residues.

In the method for manufacturing a semiconductor substrate, the underlayer film-forming composition for a metal-containing resist includes a compound [A] that is a polysiloxane compound or a polycarbosilane compound including a structural unit (a) having an aliphatic hydrocarbon group. This makes it possible to form an underlayer film for a metal-containing resist capable of exhibiting excellent pattern rectangularity and efficiently manufacture a high-quality semiconductor substrate.

The reason for this is not clear, but can be expected as follows. For example, during the organic solvent development of the exposed metal-containing resist film, in the unexposed portion, the hydrophobic aliphatic hydrocarbon group derived from the structural unit (a) included in the underlayer film for a metal-containing resist suppresses excessive adhesion to the metal-containing resist film as the upper layer, and as a result, trailing of the resist pattern is suppressed. In addition, since the underlayer film for a metal-containing resist formed from the underlayer film-forming composition for a metal-containing resist includes the structural unit (α) having a relatively hydrophobic aliphatic hydrocarbon group, the underlayer film for a metal-containing resist is easily permeated with an organic solvent for development and easily removed by the organic solvent, thereby suppressing the generation of development residues. It is presumed that good pattern rectangularity can be exhibited by these actions.

In the present specification, an “organic group” means a group having at least one carbon atom, and a “carbon number” means the number of carbon atoms constituting a group.

The underlayer film-forming composition in the present disclosure can efficiently form an underlayer film for a metal-containing resist film that is capable of exhibiting excellent pattern rectangularity.

Hereinafter, a method for manufacturing a semiconductor substrate and an underlayer film-forming composition for a metal-containing resist according to embodiments of the present disclosure will be described in detail. Combinations of suitable modes in embodiments are also preferred.

### <<Method for Manufacturing Semiconductor Substrate>>

A method for manufacturing a semiconductor substrate according to the present embodiment includes: applying an underlayer film-forming composition for a metal-containing resist directly or indirectly to a substrate (hereinafter, also referred to as a “application step (I)”); applying a composition for forming a metal-containing resist film to an underlayer film for a metal-containing resist formed by applying the underlayer film-forming composition for a metal-containing resist (hereinafter, also referred to as a “application step (II)”); exposing the metal-containing resist film formed by applying the composition for forming a metal-containing resist film to extreme ultraviolet rays (hereinafter, also referred to as an “exposing step”); and developing at least the exposed metal-containing resist film (hereinafter, also referred to as a “developing step”).

The method for manufacturing a semiconductor substrate may further include, if necessary, directly or indirectly forming an organic underlayer film on the substrate (hereinafter, also referred to as an “organic underlayer film forming step”) before the application step (I).

Further, the method for manufacturing a semiconductor substrate may further include, after the developing step, etching the underlayer film for a metal-containing resist using the resist pattern as a mask to form a pattern of the underlayer film for a metal-containing resist (hereinafter, also referred to as a “step of forming a pattern of the underlayer film for a metal-containing resist”), and performing etching using the pattern of the underlayer film for a metal-containing resist as a mask (hereinafter, also referred to as an “etching step”).

According to the method for manufacturing a semiconductor substrate, an underlayer film for a metal-containing resist that is excellent in pattern rectangularity can be formed by using the composition in the step of forming an underlayer film for a metal-containing resist.

Hereinafter, description will be made about the underlayer film-forming composition for a metal-containing resist to be used in the method for manufacturing a semiconductor substrate; and a case where optional steps: the organic underlayer film forming step before the step of forming an underlayer film for a metal-containing resist, and the step of forming a pattern of the underlayer film for a metal-containing resist and the etching step after the developing step are included.

### <Underlayer Film-Forming Composition for Metal-Containing Resist>

The composition contains a compound [A] and a solvent [B]. The composition may further contain other optional components as long as the effects of the present invention are not impaired.

The composition is suitably used for forming an underlayer film for a metal-containing resist, as the underlayer film of the metal-containing resist film. Each component contained in the composition will be described below.

### <Compound [A]>

The compound [A] has at least the structural unit (α). In the following, each structural unit of the compound [A] will be described.

### (Structural Unit (α))

The structural unit (α) is at least one selected from the group consisting of a structural unit (α-1) represented by formula (1-1) and a structural unit (α-2) represented by formula (1-2).

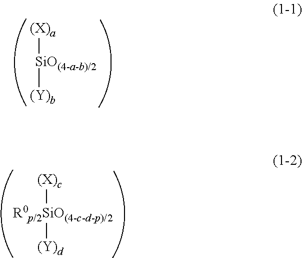

In the formula (1-1), X is a monovalent aliphatic hydrocarbon group having 1 to 20 carbon atoms or a monovalent aliphatic hydrocarbon group having 1 to 20 carbon atoms substituted with at least one halogen atom; a is an integer of 1 to 3; when a is 2 or more, the plurality of Xs are the same or different from each other; Y is a monovalent organic group having 1 to 20 carbon atoms, a hydroxy group, or a halogen atom; b is an integer of 0 to 2; when b is 2, two Ys are the same or different from each other; and a+b is 3 or less.

In the formula (1-2), X is a monovalent aliphatic hydrocarbon group having 1 to 20 carbon atoms or a monovalent aliphatic hydrocarbon group having 1 to 20 carbon atoms substituted with at least one halogen atom; c is an integer of 1 to 3; c is an integer of 1 to 3; when c is 2 or more, the plurality of X's are the same or different from each other; Y is a monovalent organic group having 1 to 20 carbon atoms, a hydroxy group, or a halogen atom; d is an integer of 0 to 2; when d is 2, two Y's are the same or different from each other; R⁰ is a substituted or unsubstituted divalent hydrocarbon group having 1 to 20 carbon atoms and bonded to two silicon atoms; p is an integer of 1 to 3; when p is 2 or more, the plurality of R⁰'s are the same or different from each other; and It is noted that c+d+p is 4 or less.

In the formula (1-1) and the formula (1-2), examples of the monovalent aliphatic hydrocarbon group having 1 to 20 carbon atoms represented by X include a monovalent chain aliphatic hydrocarbon group having 1 to 20 carbon atoms, a monovalent alicyclic hydrocarbon group having 3 to 20 carbon atoms, and a combination thereof.

Examples of the monovalent chain aliphatic hydrocarbon group having 1 to 20 carbon atoms include a monovalent chain aliphatic saturated hydrocarbon group having 1 to 20 carbon atoms and a monovalent chain aliphatic unsaturated hydrocarbon group having 1 to 20 carbon atoms. Examples of the monovalent chain aliphatic saturated hydrocarbon group having 1 to 20 carbon atoms include alkyl groups such as a methyl group, an ethyl group, a n-propyl group, an isopropyl group, a n-butyl group, a sec-butyl group, an isobutyl group, and a tert-butyl group. Examples of the monovalent chain aliphatic unsaturated hydrocarbon group having 1 to 20 carbon atoms include alkenyl groups such as an ethenyl group, a propenyl group, and a butenyl group; and alkynyl groups such as an ethynyl group, a propynyl group, and a butynyl group.

Examples of monovalent alicyclic hydrocarbon groups having 3 to 20 carbon atoms include monocyclic saturated alicyclic hydrocarbon groups such as cyclopentyl group and cyclohexyl group, polycyclic alicyclic saturated hydrocarbon groups such as a norbornyl group, an adamantyl group, a tricyclodecyl group, a tetracyclododecyl group, monocyclic alicyclic unsaturated hydrocarbon groups such as a cyclopentenyl group and a cyclohexenyl group, polycyclic alicyclic unsaturated hydrocarbon groups such as a norbornenyl group, a tricyclodecenyl group, a tetracyclododesenyl group.

The aliphatic hydrocarbon group is preferably a monovalent chain aliphatic saturated hydrocarbon group having 1 to 5 carbon atoms or a monovalent alicyclic saturated hydrocarbon group having 3 to 6 carbon atoms.

Examples of the monovalent aliphatic hydrocarbon group having 1 to 20 carbon atoms substituted with at least one halogen atom represented by X (hereinafter, also referred to as a “halogenated aliphatic hydrocarbon group”) include groups in which some or all of hydrogen atoms of the monovalent aliphatic hydrocarbon group having 1 to 20 carbon atoms are substituted with halogen atoms. Examples of the halogen atom include a fluorine atom, a chlorine atom, a bromine atom, and an iodine atom (As used herein, unless otherwise specified, the “halogen atom” includes these atoms.). The halogen atom is preferably a fluorine atom or an iodine atom. The number of halogen atoms in the halogenated aliphatic hydrocarbon group is preferably 1 to 4, and more preferably 1 to 3.

In the formula (1-1) and the formula (1-2), examples of the monovalent organic group having 1 to 20 carbon atoms represented by Y include:
a monovalent hydrocarbon group having 1 to 20 carbon atoms;
a group containing a divalent hetero atom-containing linking group between two adjacent carbon atoms or at the end of the hydrocarbon group (hereinafter, also referred to as a “group (α)”);
a group obtained by substituting some or all of the hydrogen atoms of the hydrocarbon group or the group (α) with a monovalent hetero atom-containing substituent (hereinafter, also referred to as a “group (B)”); and
a group obtained by combining at least two of the hydrocarbon group, the group (α) and the group (B) (hereinafter, also referred to as a “group (γ)”).

Examples of the monovalent hydrocarbon group having 1 to 20 carbon atoms include a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

As the monovalent chain hydrocarbon group having 1 to 20 carbon atoms, a monovalent chain aliphatic hydrocarbon group having 1 to 20 carbon atoms in the above X can be suitably employed.

As the monovalent alicyclic hydrocarbon group having 3 to 20 carbon atoms, a monovalent alicyclic hydrocarbon group having 1 to 20 carbon atoms in the above X can be suitably employed.

Examples of monovalent aromatic hydrocarbon groups having 6 to 20 carbon atoms include aryl groups such as a phenyl group, a tolyl group, a xylyl group, a naphthyl group and an anthryl group, aralkyl groups such as a benzyl group, a phenethyl group, a naphthylmethyl group and an anthrylmethyl group.

Examples of the heteroatoms that constitute the divalent heteroatom-containing linking group and the monovalent heteroatom-containing substituent include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent heteroatom-containing liking groups include, for example, —O—, —C(═O)—, —S—, —C(═S)—, —NR′—, —SO₂—, or combinations of two or more of these and the like. R′ is a hydrogen atom or a monovalent hydrocarbon group.

Examples of the monovalent hetero atom-containing substituent include a halogen atom, a hydroxy group, a carboxy group, a cyano group, an amino group, and a sulfanyl group.

Y is preferably an alkoxy group.

In the formula (1-1), a is preferably 1 or 2, and more preferably 1.

In the formula (1-1), b is preferably 0 or 1, and more preferably 0.

In the formula (1-2), c is preferably 1 or 2, and more preferably 1.

In the formula (1-2), d is preferably 0 or 1, and more preferably 0.

Examples of the substituted or unsubstituted divalent hydrocarbon group having 1 to 20 carbon atoms and bonded to two silicon atoms represented by R⁰ in the formula (1-2) include a substituted or unsubstituted divalent chain hydrocarbon group having 1 to 20 carbon atoms, a substituted or unsubstituted divalent aliphatic cyclic hydrocarbon group having 3 to 20 carbon atoms, and a substituted or unsubstituted divalent aromatic hydrocarbon group having 6 to 20 carbon atoms.

Examples of the unsubstituted divalent chain hydrocarbon group having 1 to 20 carbon atoms include chain saturated hydrocarbon groups such as a methanediyl group and an ethanediyl group, and chain unsaturated hydrocarbon groups such as an ethenediyl group and a propenediyl group.

Examples of the unsubstituted divalent aliphatic cyclic hydrocarbon group having 3 to 20 carbon atoms include monocyclic saturated hydrocarbon groups such as a cyclobutanediyl group, monocyclic unsaturated hydrocarbon groups such as a cyclobutenediyl group, polycyclic saturated hydrocarbon groups such as a bicyclo[2.2.1]heptanediyl group, and polycyclic unsaturated hydrocarbon groups such as a bicyclo[2.2.1] heptenediyl group.

Examples of the unsubstituted divalent aromatic hydrocarbon group having 6 to 20 carbon atoms include a phenylene group, a biphenylene group, a phenylene ethylene group, and a naphthylene group.

Examples of the substituent in the substituted divalent hydrocarbon group having 1 to 20 carbon atoms represented by R⁰ include a halogen atom, a hydroxy group, a cyano group, a nitro group, an alkoxy group, an acyl group, and an acyloxy group.

As R⁰, an unsubstituted chain saturated hydrocarbon group or an unsubstituted aromatic hydrocarbon group is preferable, and a methanediyl group, an ethanediyl group, or a phenylene group is more preferable.

In the formula (1-2), p is preferably 2 or 3.

Examples of X in the formula (1-1) and the formula (1-2) include structures represented by the following formulae.

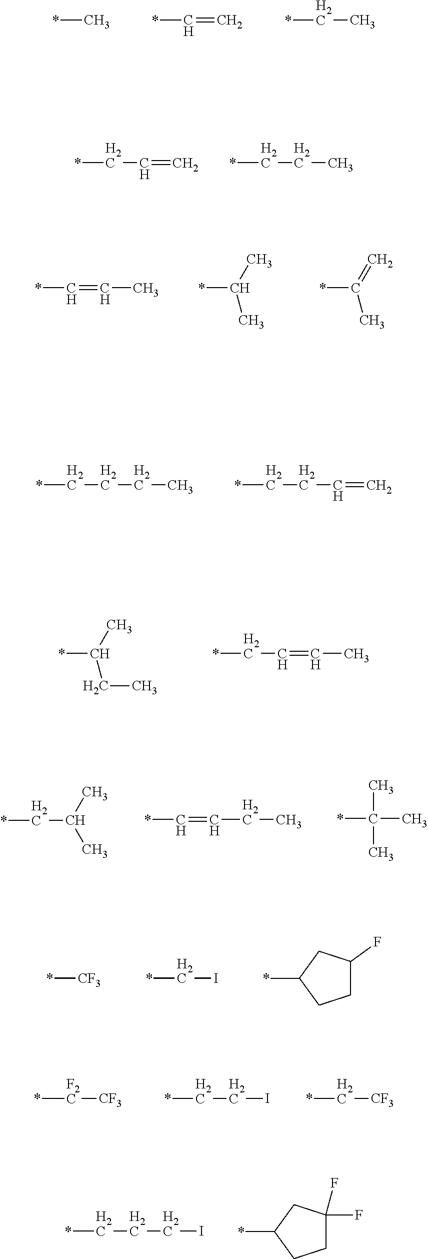

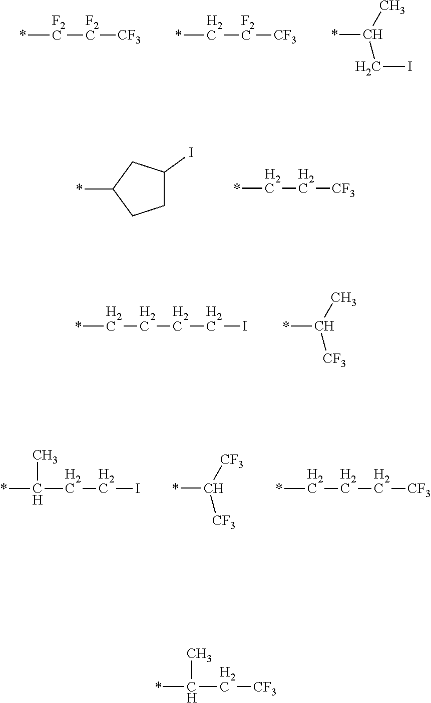

In the above formula, * is a bond with the silicon atoms in the formula (1-1) and the formula (1-2).

The total content ratio of the structural unit (α-1) and the structural unit (α-2) to all structural units constituting the compound [A] is 50 mols or more and 100 mols or less. The lower limit of the content ratio (when a plurality of types thereof is contained, a total content ratio is taken) is preferably 60 mol %, more preferably 70 mol %, and still more preferably 80 mol %. The upper limit of the content ratio is preferably 95 mol %, and more preferably 90 mol %. By setting the total content ratio of the structural unit (α-1) and the structural unit (α-2) within the above range, the pattern rectangularity can be further improved.

### (Structural Unit (β))

The compound [A] may have a structural unit (β) represented by formula (2).

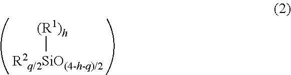

In the formula (2), R¹ is a monovalent organic group having 1 to 20 carbon atoms (containing no monovalent aliphatic hydrocarbon group and halogenated aliphatic hydrocarbon group having 1 to 20 carbon atoms), a hydroxy group, a hydrogen atom, or a halogen atom. h is 1 or 2; when h is 2, two R¹'s are the same or different from each other; R² is a substituted or unsubstituted divalent hydrocarbon group having 1 to 20 carbon atoms and bonded to two silicon atoms; q is an integer of 1 to 3; when q is 2 or more, the plurality of R²'s are the same or different from each other; and It is noted that h+q is 4 or less.

In the formula (2-1), examples of the monovalent organic group having 1 to 20 carbon atoms represented by R¹ include groups similar to the groups exemplified as the monovalent organic group having 1 to 20 carbon atoms of Y in the formula (1-1) and the formula (1-2) except that no monovalent aliphatic hydrocarbon group and halogenated aliphatic hydrocarbon group having 1 to 20 carbon atoms are contained.

R¹ is preferably a hydrogen atom, a monovalent chain hydrocarbon group, a monovalent aromatic hydrocarbon group, or a monovalent group in which a part or all of the hydrogen atoms of the monovalent hydrocarbon group are replaced with a monovalent heteroatom-containing group, more preferably a hydrogen atom, an alkyl group or an aryl group, and further preferably a hydrogen atom, a methyl group, an ethyl group, or a phenyl group.

Examples of the substituted or unsubstituted divalent hydrocarbon group having 1 to 20 carbon atoms and bonded to two silicon atoms represented by R² include groups the same as those recited as examples of the substituted or unsubstituted divalent hydrocarbon group having 1 to 20 carbon atoms and bonded to two silicon atoms of R⁰ in the formula (1-2).

As R², an unsubstituted chain saturated hydrocarbon group or an unsubstituted aromatic hydrocarbon group is preferable, and a methanediyl group, an ethanediyl group, or a phenylene group is more preferable.

h is preferably 1.

q is preferably 2 or 3.

When the compound [A] has the structural unit (β), the lower limit of the content ratio of the structural unit (β) (when a plurality of types thereof are contained, a total content ratio is taken) is preferably 4 mol %, more preferably 6 mol %, and still more preferably 8 mol % based on all structural units constituting the compound [A]. The upper limit of the content ratio is preferably 70 mol %, more preferably 60 mol %, and still more preferably 50 mol %.

### (Structural Unit (γ))

The compound [A] may have a structural unit (γ) represented by formula (3).

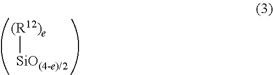

In the formula (3), R¹² is a substituted or unsubstituted monovalent alkoxy group having 1 to 20 carbon atoms, a hydroxy group, or a halogen atom. e is an integer of 0 to 3. When e is 2 or more, the plurality of R¹²s is the same or different from each other.

In the formula (3), specific examples of the monovalent alkoxy group having 1 to 20 carbon atoms represented by R¹² include alkoxy groups such as a methoxy group, an ethoxy group, a n-propyloxy group, and an isopropyloxy group. Examples of the halogen atom include a fluorine atom, a chlorine atom, a bromine atom, and an iodine atom.

In the formula (3), R¹² is preferably an alkoxy group, and more preferably a methoxy group.

In the formula (3), e is preferably an integer of 0 to 2, and more preferably 0 or 1.

When the compound [A] has the structural unit (γ), the lower limit of the content ratio of the structural unit (γ) to all the structural units constituting the compound [A] is preferably 2 mol %, more preferably 5 mol %, and even more preferably 8 mol %. The upper limit of the content ratio is preferably 70 mol %, more preferably 60 mol %, and still more preferably 55 mol %.

The lower limit of the content ratio of the compound [A] is preferably 0.1% by mass, more preferably 0.5% by mass, and still more preferably 0.8% by mass based on the total mass of the compound [A] and the solvent [B]. The upper limit of the content ratio is preferably 10% by mass, more preferably 5% by mass, and still more preferably 2% by mass.

The compound [A] is preferably in the form of a polymer. The term “polymer” refers to a compound having two or more structural units, and when two or more identical structural units are consecutive in a polymer, the structural units are also referred to as “repeating units”. When the compound [A] is in the form of a polymer, the lower limit of the polystyrene-equivalent weight-average molecular weight (Mw) of the compound [A] determined by gel permeation chromatography (GPC) is preferably 800, more preferably 1,000, still more preferably 1,200, and particularly preferably 1, 400. The upper limit of Mw is preferably 15,000, more preferably 10,000, still more preferably 7,000, and particularly preferably 3,000. The Mw of the compound [A] is measured as described in Examples.

### <Synthesis of Compound [A]>

The compound [A] is obtained, for example, through hydrolysis condensation of a polysiloxane having the structural unit (α-1), hydrolysis condensation of a polycarbosilane having the structural unit (α-2), or hydrolysis condensation of a polycarbosilane having the structural unit (α-2) with a silane compound that affords the structural unit (α-1). At the time of hydrolysis condensation, another silane compound or the like may be added, as necessary. The hydrolysis condensation can be performed by performing hydrolysis condensation in a solvent such as diisopropyl ether in the presence of water and a catalyst such as oxalic acid, and preferably purifying a solution containing the generated hydrolysis condensate through solvent substitution or the like in the presence of a dehydrating agent such as ortho ester or molecular sieve. It is considered that each hydrolyzable silane monomer is incorporated into the compound [A] through a hydrolysis condensation reaction or the like regardless of the type of the hydrolyzable silane monomer. The content ratio of the structural units (α-1) and (α-2) and other structural units in the compound [A] synthesized is usually equivalent to the ratio of the amounts of the respective monomer compounds used in the synthesis reaction.

### <Solvent [B]>

Examples of the solvent [B] include alcohol-based solvents, ketone-based solvents, ether-based solvents, ester-based solvents, nitrogen-containing solvents, and water. The solvent [B] may be used singly or two or more kinds thereof may be used in combination.

Examples of alcohol solvents include monoalcohol solvents such as methanol, ethanol, n-propanol, iso-propanol, n-butanol and iso-butanol, polyhydric alcohol solvents such as ethylene glycol, 1,2-propylene glycol, diethylene glycol and dipropylene glycol.

Examples of ketone solvents include acetone, 2-butanone, 2-pentanone, 4-methyl-2-pentanone, 2-heptanone, and cyclohexanone.

Examples of ether solvents include ethyl ether, isopropyl ether, ethylene glycol dibutyl ether, diethylene glycol monomethyl ether, diethylene glycol monoethyl ether, diethylene glycol diethyl ether, propylene glycol monomethyl ether, propylene glycol monoethyl ether, propylene glycol monopropyl ether, tetrahydrofuran and the like.

Examples of ester solvents include ethyl acetate, Y-butyrolactone, n-butyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate, dipropylene glycol monoethyl ether acetate, ethyl propionate, n-butyl propionate, methyl lactate, ethyl lactate and the like.

Examples of nitrogen-containing solvents include N, N-dimethylformamide, N, N-dimethylacetamide, N-methylpyrrolidone, and the like.

Among these, ether-based solvents or ester-based solvents are preferable, and ether-based solvents or ester-based solvents having a glycol structure are more preferable because of their excellent film-forming properties.

Examples of ether solvents and ester solvents having a glycol structure include propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate and the like. Among these, propylene glycol monomethyl ether acetate or propylene glycol monoethyl ether is preferable.

The content ratio of the ether-based solvent having a glycol structure and the ester-based solvent in the solvent [B] is preferably 20% by mass or more, more preferably 60% by mass or more, still more preferably 90% by mass or more, and particularly preferably 100% by mass.

The lower limit of the content ratio of the solvent [B] in the composition is preferably 50% by mass, more preferably 80% by mass, still more preferably 90% by mass, and particularly preferably 95% by mass. The upper limit of the content ratio is preferably 99.9% by mass, and more preferably 99% by mass.

### <Other Optional Components>

Examples of other optional components include acid generators, basic compounds (including base generators), ortho esters, radical generators, surfactants, colloidal silica, colloidal alumina, and organic polymers. The other optional components may be used singly or two or more kinds thereof may be used in combination.

### (Acid Generator)

The acid generator is a component that generates an acid through exposure to light or heating. When the composition contains an acid generator, the condensation reaction of the compound [A] can be promoted even at a relatively low temperature (including normal temperature).

Examples of the acid generator that generates an acid through exposure to light (hereinafter also referred to as “photo-acid generator”) include the acid generators described in paragraphs to in JP-A-2004-168748, and triphenylsulfonium trifluoromethanesulfonate.

Examples of the acid generator that generates an acid through heating (hereinafter also referred to as “thermal acid generator”) include onium salt-based acid generators recited as examples of photo-acid generators in WO 2022/260154, 2,4,4,6-tetrabromocyclohexadienone, benzoin tosylate, 2-nitrobenzyl tosylate, and alkyl sulfonates.

When the composition comprises an acid generator, the lower limit of the content of the acid generator is preferably 0.001 parts by mass, and more preferably 0.01 parts by mass based on 100 parts by mass of the compound [A]. The upper limit of the content of the acid generator is preferably 5 parts by mass, and more preferably 1 part by mass based on 100 parts by mass of the compound [A].

### (Basic Compound)

The basic compound promotes a curing reaction of the composition, and as a result, enhance the strength or the like of a film to be formed. In addition, the basic compound improves the peelability of the film with an acidic solution. Examples of the basic compound include a compound having a basic amino group, and a base generator that generates a compound having a basic amino group by the action of an acid or the action of heat. Examples of the compound having a basic amino group include amine compounds. Examples of the base generator include an amide group-containing compound, a urea compound, and a nitrogen-containing heterocyclic compound. Examples of the amine compound, the amide group-containing compound, the urea compound, and the nitrogen-containing heterocyclic compound include compounds described in paragraphs to of JP-A-2016-27370.

When the composition comprises a basic compound, the lower limit of the content of the basic compound is preferably 0.001 parts by mass, and more preferably 0.01 parts by mass, based on 100 parts by mass of the compound [A]. The upper limit of the content is preferably 5 parts by mass, and more preferably 1 part by mass.

### (Ortho Ester)

The ortho ester is an ester form of an orthocarboxylic acid. The ortho ester reacts with water to afford a carboxylate ester or the like. Examples of the ortho ester include orthoformate esters such as methyl orthoformate, ethyl orthoformate, and propyl orthoformate, orthoacetate esters such as methyl orthoacetate, ethyl orthoacetate, and propyl orthoacetate, and orthopropionate esters such as methyl orthopropionate, ethyl orthopropionate, and propyl orthopropionate. Among them, an orthoformate is preferable, and trimethyl orthoformate is more preferable.

When the composition comprises an ortho ester, the lower limit of the content of the ortho ester is preferably 0.1 parts by mass, more preferably 0.5 parts by mass, and still more preferably 1 part by mass, based on 100 parts by mass of the compound [A]. The upper limit of the content is preferably 30% by mass, more preferably 20% by mass, and still more preferably 10% by mass.

### <Method for Preparing a Underlayer Film-Forming Composition for a Metal-Containing Resist>

The method for preparing the composition is not particularly limited, and for example, the composition can be prepared by mixing a solution of the compound [A], the solvent [B], and other optional components which are used as necessary in a prescribed ratio, and then filtering the resulting mixed solution through a filter having a pore size of 0.4 μm or less.

### [Organic Underlayer Film Forming Step]

In this step, an organic underlayer film is formed directly or indirectly on the substrate before the step of forming an underlayer film for a metal-containing resist. This step is an arbitrary step. Through this step, an organic underlayer film is formed directly or indirectly on the substrate.

The organic underlayer film can be formed by applying a composition for forming an organic underlayer film. The method of forming the organic underlayer film by applying the composition for forming an organic underlayer film may be, for example, a method in which a coating film formed by directly or indirectly applying the composition for forming an organic underlayer film to a substrate is cured by heating or exposure. As the composition for forming an organic underlayer film, for example, “HM8006” manufactured by JSR Corporation can be used. Various conditions for heating or exposure can be appropriately determined according to the type of the composition for forming an organic underlayer film to be used.

Examples of a case where an organic underlayer film is indirectly formed on a substrate include a case where an organic underlayer film is formed on a low dielectric insulating film formed on a substrate.

### [Application Step (I)]

In this step, the underlayer film-forming composition for a metal-containing resist is applied directly or indirectly to the substrate. By this step, a coating film of the composition is formed directly or indirectly on the substrate, and the coating film is usually cured by heating to form an underlayer film for a metal-containing resist as a resist underlayer film.

Examples of substrates include insulating films such as silicon oxide, silicon nitride, silicon oxynitride and polysiloxane, and resin substrates. Also, the substrate may be a substrate having patterning such as a wiring groove (trench), a plug groove (vias) and the like.

The method for applying the underlayer film-forming composition for a metal-containing resist is not particularly limited, and examples thereof include a spin coating method.

Examples of the case where the underlayer film-forming composition for a metal-containing resist is applied indirectly to the substrate include a case where the underlayer film-forming composition for a metal-containing resist is applied to another film formed on the substrate. Other films formed on the substrate include, for example, an organic underlayer film which is formed by the organic underlayer film forming step described above, an antireflection film, a low dielectric insulating film, and the like.

When the coating film is heated, the atmosphere is not particularly limited, and examples thereof include air atmosphere, nitrogen atmosphere, and the like. Heating of the coating film is usually performed in the air atmosphere. Various conditions such as the heating temperature and the heating time when the coating film is heated can be appropriately determined. The lower limit of the heating temperature is preferably 90° C., more preferably 150° C., and even more preferably 200° C. The upper limit of the heating temperature is preferably 550° C., more preferably 450° C., and even more preferably 300° C. The lower limit of the heating time is preferably 15 seconds, more preferably 30 seconds. The upper limit of the heating time is preferably 1,200 seconds, more preferably 600 seconds.

When the underlayer film-forming composition for a metal-containing resist contains an acid generator, and the acid generator is a radiation-sensitive acid generator, the formation of the underlayer film for a metal-containing resist can be accelerated by combining heating and exposure. Radiation used for exposure includes, for example, the same radiation as exemplified in the exposing step described later.

The lower limit of the average thickness of the underlayer film for a metal-containing resist formed by this step is preferably 1 nm, more preferably 2 nm, and even more preferably 3 nm. The upper limit of the average thickness is preferably 30 nm, more preferably 10 nm, still more preferably 6 nm, and particularly preferably 5 nm. The method for measuring the average thickness of the underlayer film for a metal-containing resist is described in Examples.

### [Application Step (II)]

In this step, a composition for forming a metal-containing resist film is applied to the underlayer film for a metal-containing resist formed by applying the underlayer film-forming composition for a metal-containing resist. By this step, a metal-containing resist film is formed on the underlayer film for a metal-containing resist.

The method for applying the composition for forming a metal-containing resist film is not particularly limited, and examples thereof include a spin coating method.

To explain this step in more detail, for example, after applying a composition for forming a metal-containing resist film so that the formed metal-containing resist film has a predetermined thickness, pre-baking (hereinafter also referred to as “PB”) is performed to volatilize the solvent in the applied film to form a resist film.

The lower limit of the average thickness of the metal-containing resist film formed by this step is preferably 10 nm, more preferably 20 nm, and even more preferably 30 nm. The upper limit of the average thickness is preferably 60 nm, more preferably 50 nm, and even more preferably 40 nm.

The PB temperature and PB time can be appropriately determined according to the type of a composition for forming a metal-containing resist film used. The lower limit of the PB temperature is preferably 30° C., more preferably 50° C. The upper limit of the PB temperature is preferably 200° C., more preferably 150° C. The lower limit of the PB time is preferably 10 seconds, more preferably 30 seconds. The upper limit of the PB time is preferably 600 seconds, more preferably 300 seconds.

Examples of the composition for forming a metal-containing resist film used in this step include a composition for forming a metal-containing resist film including a compound containing a metal atom (hereinafter, also referred to as a “metal-containing compound [P]”).

### <Composition for Forming Metal-Containing Resist Film>

The composition for forming a metal-containing resist film contains a metal-containing compound [P] in an amount of 50% by mass or more in terms of solid content. The composition for forming a metal-containing resist film preferably further contains a solvent [Q], and may further contain other components.

### (Metal-Containing Compound [P])

The metal-containing compound [P] is a compound containing a metal atom. The metal-containing compound [P] may be used singly or in combination of two or more kinds thereof. In addition, the metal atom constituting the metal-containing compound [P] may be used singly or in combination of two or more kinds thereof. Here, the “metal atom” is a concept including a metalloid, that is, boron, silicon, germanium, arsenic, antimony, and tellurium.

The metal atom constituting the metal-containing compound [P] is not particularly limited. Examples thereof include metal atoms of Groups 3 to 16. Specific examples of the metal atom include a metal atom of Group 4 such as titanium, zirconium, and hafnium; a metal atom of Group 5 such as tantalum; a metal atom of Group 6 such as chromium and tungsten; a metal atom of Group 8 such as iron and ruthenium; a metal atom of Group 9 such as cobalt; a metal atom of Group 10 such as nickel; a metal atom of Group 11 such as copper; a metal atom of Group 12 such as zinc, cadmium, and mercury; a metal atom of Group 13 such as boron, aluminum, gallium, indium, and thallium; a metal atom of Group 14 such as germanium, tin, and lead; a metal atom of Group 15 such as antimony and bismuth; and a metal atom of Group 16 such as tellurium.

The metal atom constituting the metal-containing compound [P] preferably includes a first metal atom belonging to Group 4, Group 12, or Group 14 and belonging to Period 4, Period 5, or Period 6 in the periodic table. That is, the metal atom preferably contains at least one of titanium, zirconium, hafnium, zinc, cadmium, mercury, germanium, tin, and lead. As described above, the metal-containing compound [P] contains the first metal atom to further promote the release of secondary electrons in the exposed portion of the resist film and the change in solubility of the metal-containing compound [P] in a developer due to the secondary electrons and the like. As a result, the pattern rectangularity can be improved. The first metal atom is preferably tin or zirconium.

The metal-containing compound [P] preferably further has an atom other than the metal atom. Examples of the other atom include a carbon atom, a hydrogen atom, an oxygen atom, a nitrogen atom, a phosphorus atom, a sulfur atom, and a halogen atom. Among these atoms, a carbon atom, a hydrogen atom, and an oxygen atom are preferable. The other atom in the metal-containing compound [P] can be used singly or in combination of two or more kinds thereof.

In the composition for forming a metal-containing resist film, the lower limit of the content of the metal-containing compound [P] in terms of solid content is preferably 70% by mass, more preferably 90% by mass, and still more preferably 95% by mass. The content may be 100% by mass. Here, the solid content in the composition for forming a metal-containing resist film refers to components other than the solvent [Q] described later.

### (Synthesis Method of Metal-Containing Compound [P])

The metal-containing compound [P] can be obtained, for example, by a method of performing a hydrolysis condensation reaction, a ligand exchange reaction, or the like on a metal compound having a metal atom and a hydrolyzable group, a hydrolysate of the metal compound, a hydrolysis condensation product of the metal compound, or a combination thereof. The metal compound can be used singly or in combination of two or more kinds thereof.

The metal-containing compound [P] is preferably derived from a metal compound having a metal atom and a hydrolyzable group and represented by formula (4) (hereinafter, also referred to as a “metal compound (1)”). By using such a metal compound (1), a stable metal-containing compound [P] can be obtained.

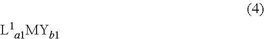

In the formula (4), M is a metal atom; L¹ is a ligand or a monovalent organic group having 1 to 20 carbon atoms; a1 is an integer of 0 to 6; when a1 is 2 or more, the plurality of Lis may be the same or different from each other; Y is a monovalent hydrolyzable group; b1 is an integer of 2 to 6; the plurality of Ys may be the same or different from each other; and L¹ is a ligand or an organic group that is not Y.

The metal atom represented by M is preferably the first metal atom, and more preferably tin.

The hydrolyzable group represented by Y can be appropriately changed according to the metal atom represented by M. Examples thereof include a substituted or unsubstituted ethynyl group, a halogen atom, an alkoxy group, an acyloxy group, and a substituted or unsubstituted amino group.

As the substituent in the substituted or unsubstituted ethynyl group and the substituted or unsubstituted amino group represented by Y, a monovalent hydrocarbon group having 1 to 20 carbon atoms is preferable, a chain hydrocarbon group is more preferable, and an alkyl group is still more preferable.

Examples of the halogen atom represented by Y include a fluorine atom, a chlorine atom, a bromine atom, and an iodine atom. Among them, a chlorine atom is preferable.

Examples of the alkoxy group represented by Y include a methoxy group, an ethoxy group, a n-propoxy group, an i-propoxy group, and a n-butoxy group. Among them, an ethoxy group, an i-propoxy group, and a n-butoxy group are preferable.

Examples of the acyloxy group represented by Y include a formyl group, an acetoxy group, an ethyryloxy group, a propionyloxy group, a n-butyryloxy group, a t-butyryloxy group, a t-amyryloxy group, a n-hexanecarbonyloxy group, and a n-octanecarbonyloxy group. Among them, an acetoxy group is preferable.

Examples of the substituted or unsubstituted amino group represented by Y include an amino group, a methylamino group, a dimethylamino group, a diethylamino group, and a dipropylamino group. Among them, a dimethylamino group and a diethylamino group are preferable.

Hereinafter, preferred combinations of the metal atom represented by M and the hydrolyzable group represented by Y will be described. When the metal atom represented by M is tin, the hydrolyzable group represented by Y is preferably a substituted or unsubstituted ethynyl group, a halogen atom, an alkoxy group, an acyloxy group, and a substituted or unsubstituted amino group, and more preferably a halogen atom. When the metal atom represented by M is germanium, the hydrolyzable group represented by Y is preferably a halogen atom, an alkoxy group, an acyloxy group, and a substituted or unsubstituted amino group. When the metal atom represented by

M is hafnium, zirconium, and titanium, the hydrolyzable group represented by Y is preferably a halogen atom, an alkoxy group, and an acyloxy group.

Examples of the ligand represented by L¹ include a monodentate ligand and a multidentate ligand.

Examples of the monodentate ligand include a hydroxo ligand, a nitro ligand, and ammonia.

Examples of the multidentate ligand include a hydroxy acid ester, a β-diketone, a β-ketoester, a malonic acid diester in which a carbon atom at the x-position is optionally substituted, a hydrocarbon having a n bond, a ligand derived from these compounds, and a diphosphine.

Examples of the diphosphine include 1,1-bis(diphenylphosphino) methane, 1,2-bis(diphenylphosphino) ethane, 1,3-bis(diphenylphosphino) propane, 2,2′-bis(diphenylphosphino)-1,1′-binaphthyl, and 1,1′-bis(diphenylphosphino) ferrocene.

Examples of the monovalent organic group represented by L¹ include groups similar to the groups exemplified as the monovalent organic group having 1 to 20 carbon atoms represented by Y in the formula (1-1) and the formula (1-2). The lower limit of the carbon number in the monovalent organic group represented by L¹ is preferably 2, and more preferably 3. On the other hand, the upper limit of the carbon number is preferably 10, and more preferably 5. The monovalent organic group represented by L¹ is preferably a substituted or unsubstituted hydrocarbon group, more preferably a substituted or unsubstituted chain hydrocarbon group or a substituted or unsubstituted aromatic hydrocarbon group, still more preferably a substituted or unsubstituted alkyl group or a substituted or unsubstituted aralkyl group, and particularly preferably an isopropyl group or a benzyl group.

a1 is preferably 1 or 2, and more preferably 1.

b1 is preferably an integer of 2 to 4. By setting b1 to the above numerical value, the content ratio of the metal atom in the metal-containing compound [P] can be increased, and the generation of secondary electrons by the metal-containing compound [P] can be more effectively promoted. As a result, the pattern rectangularity can be improved.

As the metal compound (1), a metal halide compound is preferable, and isopropyltin trichloride or benzyltin trichloride is more preferable.

Examples of the method for performing a hydrolysis condensation reaction on the metal compound (1) include a method in which the metal compound (1) is stirred in water or a solvent containing water in the presence of a base such as tetramethylammonium hydroxide, which is used as necessary. In this case, another compound having a hydrolyzable group may be added, as necessary. The lower limit of the amount of water used in the hydrolysis condensation reaction is preferably 0.2 times mol, more preferably 1 time mol, and still more preferably 3 times mol, in the number of moles, based on the hydrolyzable group of the metal compound (1) and the like. By setting the amount of water in the hydrolysis condensation reaction within the above range, the metal-containing compound [P] can be efficiently obtained.

In the synthesis reaction of the metal-containing compound [P], in addition to the metal compound (1), a compound capable of serving as a multidentate ligand represented by L¹ in the compound of the formula (4), a compound capable of serving as a bridging ligand, or the like may be added. Examples of the compound capable of serving as a bridging ligand include compounds having two or more groups capable of serving as a ligand, such as a hydroxy group, an isocyanate group, an amino group, an ester group, and an amide group.

In the synthesis reaction of the metal-containing compound [P], the lower limit of the temperature is preferably 0° C., and more preferably 10° C. The upper limit of the temperature is preferably 150° C., more preferably 100° C., and still more preferably 50° C.

In the synthesis reaction of the metal-containing compound [P], the lower limit of the time is preferably 1 minute, more preferably 10 minutes, and still more preferably 1 hour. The upper limit of the time is preferably 100 hours, more preferably 50 hours, still more preferably 24 hours, and particularly preferably 4 hours.

### (Solvent [Q])

The solvent [Q] is preferably an organic solvent. Specific examples of the organic solvent include organic solvents similar to those exemplified as the solvent [B] in the underlayer film-forming composition for a metal-containing resist described above.

As the solvent [Q], an ether-based solvent is preferable, and propylene glycol monoethyl ether is more preferable.

### (Other Optional Components)

The composition for forming a metal-containing resist film may contain other optional components such as a compound capable of serving as a ligand, and a surfactant, in addition to the metal-containing compound [P] and the solvent [Q].

### (Compound Capable of Serving as Ligand)

Examples of the compound capable of serving as a ligand include compounds capable of serving as a multidentate ligand or a bridging ligand, and specifically include the same compounds as the compounds capable of serving as a multidentate ligand or a bridging ligand exemplified in the synthesis method of the metal-containing compound [P].

### (Surfactant)

The surfactant is a component that exhibits an action of improving coatability, striation, and the like. Examples of the surfactant include nonionic surfactants, including polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate. Examples of the product name thereof include KP341 (manufactured by Shin-Etsu Chemical Co., Ltd.), POLYFLOW No. 75, POLYFLOW NO. 95 (both manufactured by Kyoeisha Chemical Co., Ltd.), EFTOP EF301, EFTOP EF303, EFTOP EF352 (all manufactured by Tohkem Products Corporation), MEGAFACE F171, MEGAFACE F173 (both manufactured by DIC), Fluorad FC430, Fluorad FC431 (both manufactured by Sumitomo 3M Limited), ASAHIGUARD AG710, SURFLON S-382, SURFLON SC-101, SURFLON SC-102, SURFLON SC-103, SURFLON SC-104, SURFLON SC-105, SURFLON SC-106 (all manufactured by Asahi Glass Co., Ltd.)

### (Preparation Method of Composition for Forming Metal-Containing Resist Film)

The composition for forming a metal-containing resist film can be prepared, for example, by mixing the metal-containing compound [P], and if necessary, other optional components such as the solvent [Q], in a predetermined ratio, and preferably filtering the obtained mixture through a membrane filter having a pore size of 0.4 μm or less. When the composition for forming a metal-containing resist film includes: the metal-containing compound [P]; and the solvent [Q], the content ratio of the metal-containing compound [P] to components other than the solvent [Q] in the composition for forming a metal-containing resist film is preferably 50% by mass or more. The lower limit of the content ratio of the metal-containing compound [P] is more preferably 60% by mass, and still more preferably 70% by mass. On the other hand, the upper limit of the content ratio is preferably 100% by mass, but may be 98% by mass or 95% by mass.

### [Exposing Step]

In this step, the metal-containing resist film formed by applying the composition for forming a metal-containing resist film is exposed to extreme ultraviolet rays (having a wavelength of 13.5 nm or the like, also referred to as “EUV”).

This step causes a difference in solubility in a developer, between an exposed portion and an unexposed portion of the resist film. The exposure conditions can be appropriately determined depending on the type of the composition for forming a resist film to be used, and the like.

In addition, in this step, post-exposure bake (hereinafter also referred to as “PEB”) can be performed in order to improve the performance of the resist film such as resolution, pattern profile, developability, etc. after the exposure. The PEB temperature and PEB time can be appropriately determined according to the type of composition for forming a resist film used. The lower limit of the PEB temperature is preferably 50° C., more preferably 70° C. The upper limit of the PEB temperature is preferably 200° C., more preferably 150° C. The lower limit of the PEB time is preferably 10 seconds, more preferably 30 seconds. The upper limit of the PEB time is preferably 600 seconds, more preferably 300 seconds.

### [Developing Step]

In this step, at least the exposed metal-containing resist film is developed. Examples of the developer to be used for the development include an aqueous alkaline solution (alkaline developer) and an organic solvent-containing solution (organic solvent developer). For example, in the case of the positive type using an alkaline developer, the exposed portion of the metal-containing resist film has been enhanced in solubility in an alkaline aqueous solution. Therefore, a positive type resist pattern is formed by removing the exposed portion through alkali development. In the case of the negative type using an organic solvent developer, the exposed portion of the metal-containing resist film has been lowered in solubility in an organic solvent. Therefore, a negative type resist pattern is formed by removing the unexposed portion, which is relatively soluble in an organic solvent, through organic solvent development.

The developer used in alkaline development is not particularly limited, and known developers can be used. Examples of developer for alkaline development include an alkaline aqueous solution containing at least one of dissolved alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, and the like. Among these, a TMAH aqueous solution is preferable, and a 2.38% by mass TMAH aqueous solution is more preferable.

Examples of the developer used for organic solvent development include the same developer as those exemplified as the solvent for the underlayer film-forming composition for a metal-containing resist described above. The organic solvent is preferably a ketone-based solvent and an ester-based solvent, and more preferably 2-heptanone and propylene glycol monomethyl ether acetate.

The development of the exposed metal-containing resist film is preferably organic solvent development.

In this step, washing and/or drying may be performed after the development.

### [Step of Forming Pattern of Underlayer Film for Metal-Containing Resist]

In this step, the underlayer film for a metal-containing resist is etched using the resist pattern as a mask to form a pattern of the underlayer film for a metal-containing resist.

The above etching may be dry etching or wet etching, but dry etching is preferred.

Dry etching can be performed using, for example, a known dry etching apparatus. The etching gas used for dry etching can be appropriately selected according to the elemental composition of the underlayer film for a metal-containing resist to be etched, and for example, fluorine-based gases such as CHF₃, CF₄, C₂F₆, C₃F₈ and SF₆, chlorine-based gases such as Cl₂ and BCl₃, oxygen-based gases such as O₂, O₃ and H₂O, reducing gases such as H₂, NH₃, CO, CO₂, CH₄, C₂H₂, C₂H₄, C₂H₆, C₃H₄, C₃H₆, C₃H₈, HF, H¹, HBr, HCl, and NO, and inert gases such as He, N₂ and Ar are used. These gases can also be mixed and used. For dry etching of the underlayer film for a metal-containing resist, a fluorine-based gas is usually used, and a mixture of a fluorine-based gas, an oxygen-based gas, and an inert gas is preferably used.

### [Etching Step]

In this step, etching is performed using the pattern of the underlayer film for a metal-containing resist as a mask. More specifically, etching is performed one or more times using as a mask the pattern formed in the underlayer film for a metal-containing resist obtained in the step of forming a pattern of the underlayer film for a metal-containing resist to obtain a patterned substrate.

When an organic underlayer film is formed on the substrate, the organic underlayer film is etched using the pattern of the underlayer film for a metal-containing resist as a mask to form a pattern of the organic underlayer film, and then the substrate is etched using this organic underlayer film pattern as a mask. Thus, a pattern is formed on the substrate.

The above etching may be dry etching or wet etching, but dry etching is preferred.

Dry etching for forming a pattern on the organic underlayer film can be performed using a known dry etching apparatus. The etching gas used for dry etching can be appropriately selected depending on the elemental composition of the underlayer film for a metal-containing resist and the organic underlayer film to be etched. As the etching gas, the gas for etching the underlayer film for a metal-containing resist described above can be suitably used, and these gases can also be mixed and used. An oxygen-based gas is usually used for dry etching of the organic underlayer film using the pattern of the underlayer film for a metal-containing resist as a mask.

Dry etching for forming a pattern on the substrate using the organic underlayer film pattern as a mask can be performed using a known dry etching apparatus. The etching gas used for dry etching can be appropriately selected depending on the elemental composition of the underlayer film for a metal-containing resist and the substrate to be etched, and the like. For example, etching gases similar to those exemplified as the etching gas used for the dry etching of the organic underlayer film may be used. Etching may be performed a plurality of times with different etching gases. Etching may be performed a plurality of times with different etching gases. After the etching, a semiconductor substrate having a prescribed pattern can be manufactured.

### <<Underlayer Film-Forming Composition for Metal-Containing Resist>>

The underlayer film-forming composition for a metal-containing resist includes the compound [A] and the solvent [B]. As the composition, the underlayer film-forming composition for a metal-containing resist to be used in the above-described method for manufacturing a semiconductor substrate can be suitably employed.

### EXAMPLES

Hereinafter, Examples are described. The following Examples merely illustrate typical Examples of the present invention, and the Examples should not be construed to narrow the scope of the present invention.

In the present Examples, the weight-average molecular weight (Mw) of the compound (a) as an intermediate and the compound [A], the concentration of a solution of the compound [A], and the average thickness of a film were measured by the following methods.

### [Weight-Average Molecular Weight (Mw)]

The weight-average molecular weight (Mw) of compound (a-1) to compound (a-13) as the compound [a] and the compound [A] was measured by gel permeation chromatography (GPC) using GPC columns, available from Tosoh Corporation (“G2000HXL” x 2, “G3000HXL” x 1, and “G4000HXL” x 1) under the following conditions.
Eluant: tetrahydrofuran (manufactured by Wako Pure Chemical Industries, Ltd.)
Flow rate: 1.0 mL/min
Sample concentration: 1.0% by mass
Sample injection amount: 100 μL
Column temperature: 40° C.
Detector: differential refractometer
Standard substance: monodisperse polystyrene

### [Concentration of Solution of Compound [A]]

The concentration (% by mass) of a solution of the compound [A] was calculated by firing 0.5 g of the solution of the compound [A] at 250° C. for 30 minutes, measuring a mass of a residue thus obtained, and dividing the mass of the residue by the mass of the solution of the compound [A].

### [Average Thickness of Film]

The average thickness of the film was measured by using a spectroscopic ellipsometer (“M2000D”, available from J. A. WOOLLAM CO.). More specifically, thicknesses of the film formed on a silicon wafer were measured at optional nine points located at an interval of 5 cm including the center of the film, and the average value of the film thicknesses was calculated, and taken as the average thickness.

<Synthesis of Compounds (a-1) to (a-13)>

The monomers used for synthesis in Synthesis Examples 1-1 to 1-13 (hereinafter also referred to as “monomers (H-1), (S-1) to (S-9)”) are shown below.

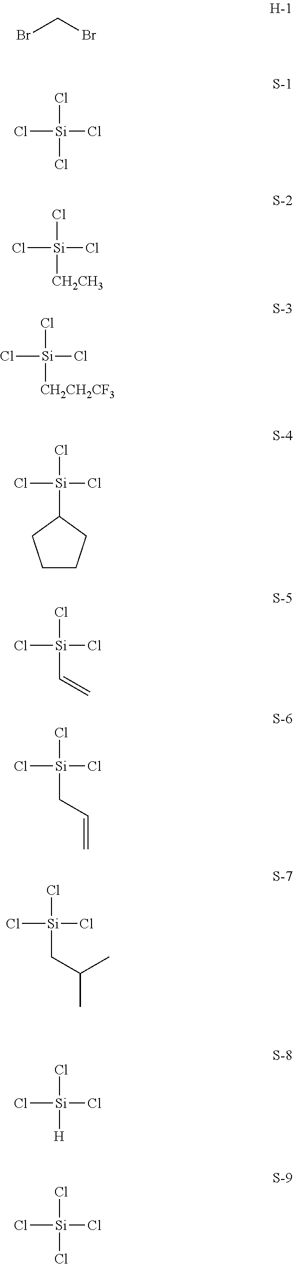

### [Synthesis Example 1-1] (Synthesis of Compound (a-1))

To a reaction vessel purged with nitrogen, 5.83 g of 5 magnesium and 11.12 g of tetrahydrofuran were added, and the mixture was stirred at 20° C. Next, 17.38 g of monomer (H-1), and 14.94 g of monomer (S-1) (molar ratio: 50/50 (mol %)) were dissolved in 111.15 g of tetrahydrofuran to prepare a monomer solution. The temperature in the reaction vessel was adjusted 10 to 20° C., and the monomer solution was added dropwise thereto over 1 hour with stirring. A time point of completion of the dropwise addition was taken as a start time of a reaction, and the mixture was stirred at 40° C. for 1 hour and then at 60° C. for 3 hours. Then 66.69 g of tetrahydrofuran was added, and the mixture was cooled to 10° C. or lower, affording a polymerization reaction liquid. Subsequently, 30.36 g of triethylamine was added to the polymerization reaction liquid, and then 9.61 g of methanol was added dropwise thereto over 10 minutes with stirring. A time point of completion of the dropwise addition was taken as a start time of a reaction, and the mixture was stirred at 20° C. for 1 hour. Then the reaction liquid was charged into 220 g of diisopropyl ether, and the precipitated salt was filtered off. Next, tetrahydrofuran, diisopropyl ether, triethylamine, and methanol in the filtrate were removed using an evaporator. 50 g of diisopropyl ether was added to the residue obtained, the precipitated salt was filtered off, and diisopropyl ether was added to the filtrate, affording compound (a-1) having a concentration of 12% by mass. The Mw of compound (a-1) was 850.

### [Synthesis Examples 1-2 to 1-13] (Synthesis of Compounds (a-2) to (a-13))

Diisopropyl ether solutions of compounds (a-2) to (a-13) were obtained in the same manner as in Synthesis Example 1-1 except that the monomers of the types and use amounts shown in the following Table 1 were used, respectively. The Mw of the compounds (a) obtained is also disclosed in Table 1. “-” in Table 1 indicates that the corresponding monomer was not used.

TABLE 1

| | Compound | Charged amount of each monomer (mol %) | | | | | | | | | | Concentration | |
|---|---|---|---|---|---|---|---|---|---|---|---|---|---|
| | (a) | H-1 | S-1 | S-2 | S-3 | S-4 | S-5 | S-6 | S-7 | S-8 | S-9 | (% by mass) | Mw |
| Synthesis | a-1 | 50 | 50 | — | — | — | — | — | — | — | — | 12 | 850 |
| Example 1-1 | | | | | | | | | | | | | |
| Synthesis | a-2 | 50 | 45 | — | — | — | — | — | — | 5 | — | 12 | 900 |
| Example 1-2 | | | | | | | | | | | | | |
| Synthesis | a-3 | 50 | 35 | — | — | — | — | — | — | 15 | — | 12 | 950 |
| Example 1-3 | | | | | | | | | | | | | |
| Synthesis | a-4 | 50 | 25 | — | — | — | — | — | — | 25 | — | 12 | 1,000 |
| Example 1-4 | | | | | | | | | | | | | |
| Synthesis | a-5 | 50 | 45 | — | — | — | — | — | — | — | 5 | 12 | 1,000 |
| Example 1-5 | | | | | | | | | | | | | |
| Synthesis | a-6 | 50 | — | 45 | — | — | — | — | — | 5 | — | 12 | 850 |
| Example 1-6 | | | | | | | | | | | | | |
| Synthesis | a-7 | 50 | — | — | 45 | — | — | — | — | 5 | — | 12 | 850 |
| Example 1-7 | | | | | | | | | | | | | |
| Synthesis | a-8 | 50 | — | — | — | 45 | — | — | — | 5 | — | 12 | 800 |
| Example 1-8 | | | | | | | | | | | | | |
| Synthesis | a-9 | 50 | — | — | — | — | 45 | — | — | 5 | — | 12 | 850 |
| Example 1-9 | | | | | | | | | | | | | |
| Synthesis | a-10 | 50 | — | — | — | — | — | 45 | — | 5 | — | 12 | 800 |
| Example 1-10 | | | | | | | | | | | | | |
| Synthesis | a-11 | 50 | — | — | — | — | — | — | 45 | 5 | — | 12 | 800 |
| Example 1-11 | | | | | | | | | | | | | |
| Synthesis | a-12 | 50 | 25 | — | 25 | — | — | — | — | — | — | 12 | 800 |
| Example 1-12 | | | | | | | | | | | | | |
| Synthesis | a-13 | 50 | 22.5 | — | — | — | — | — | — | 27.5 | — | 12 | 1,100 |
| Example 1-13 | | | | | | | | | | | | | |

### <Synthesis of Compound [A]>

The monomers (hereinafter also referred to as “monomers (M-1) to (M-9)”) used for synthesis in Synthesis Examples 2-1 to 2-29 are shown below. In addition, in the following Synthesis Examples 2-1 to 2-29, molt means a value taken when the total number of moles of silicon atoms in the compounds (a-1) to (a-13) used and the monomers (M-1) to (M-9) used is 100 mol %.

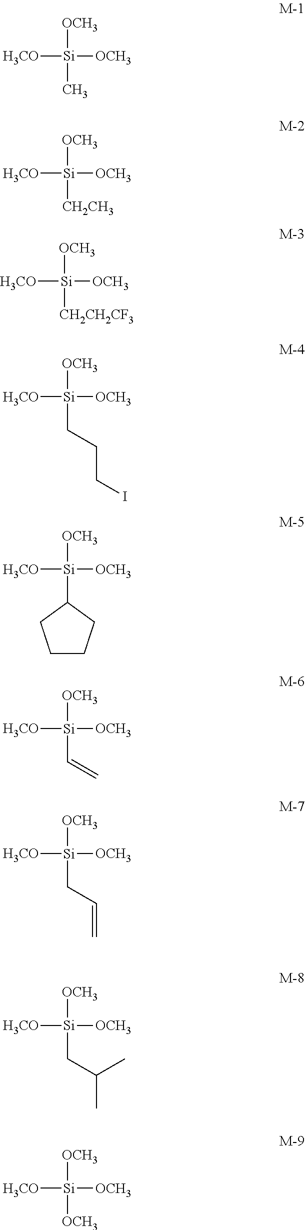

### [Synthesis Example 2-1] (Synthesis of Compound (A-1))

A reaction vessel was charged with 23.87 g of the diisopropyl ether solution of compound (a-1) obtained in Synthesis Example 1-1 and 24.29 g of acetone. The temperature in the reaction vessel was adjusted to 30° C., and 1.84 g of a 3.2% by mass aqueous solution of oxalic acid was added dropwise thereto over 20 minutes with stirring. A time point of completion of the dropwise addition was taken as a start time of a reaction, and the mixture was stirred at 40° C. for 4 hours. Then the inside of the reaction vessel was cooled to 30° C. or lower. Next, 25.0 g of diisopropyl ether and 150 g of water were added to this reaction vessel, and liquid separation extraction was performed. Thereafter, to the obtained organic layer was added 75 g of propylene glycol monomethyl ether acetate, and then water, acetone, diisopropyl ether, alcohols produced by the reaction, and excessive propylene glycol monomethyl ether acetate were removed using an evaporator. Subsequently, 5.0 g of trimethyl orthoformate as a dehydrating agent was added to the obtained solution, and the mixture was reacted at 40° C. for 1 hour, and then the inside of the reaction vessel was cooled to 30° C. or lower. Alcohols generated through the reaction, esters, trimethyl orthoformate, and excess propylene glycol monomethyl ether acetate were removed using the evaporator, affording a 5% by mass solution of compound (A-1) as the compound [A]. The Mw of compound (A-1) was 1,800.

### [Synthesis Examples 2-2 to 2-29] (Synthesis of Compounds (A-2) to (A-26) and (AJ-1) to (AJ-3))

Propylene glycol monomethyl ether acetate or propylene glycol monoethyl ether solutions of compounds (A-2) to (A-26) and (AJ-1) to (AJ-3) as the compound [A] were obtained in the same manner as in Synthesis Example 2-1 except that the compounds and the monomers of the types and amounts shown in the following Table 2 were used. The “-” in the columns of monomer in the following Table 2 indicates that the corresponding monomer was not used. The concentration (% by mass) of the obtained solution of the compound [A] and the Mw of the compound [A] are also shown in Table 2.

TABLE 2

| | Compound | Charged amount of compound and each monomer (Si mol %) | | | | | | | | | | | Concentration | |
|---|---|---|---|---|---|---|---|---|---|---|---|---|---|---|
| | [A] | Compound | | M-1 | M-2 | M-3 | M-4 | M-5 | M-6 | M-7 | M-8 | M-9 | (% by mass) | Mw |
| Synthesis | A-1 | a-1 | 100 | — | — | — | — | — | — | — | — | — | 5 | 1800 |
| Example 2-1 | | | | | | | | | | | | | | |
| Synthesis | A-2 | a-2 | 100 | — | — | — | — | — | — | — | — | — | 5 | 1900 |
| Example 2-2 | | | | | | | | | | | | | | |
| Synthesis | A-3 | a-3 | 100 | — | — | — | — | — | — | — | — | — | 5 | 2000 |
| Example 2-3 | | | | | | | | | | | | | | |
| Synthesis | A-4 | a-4 | 100 | — | — | — | — | — | — | — | — | — | 5 | 2200 |
| Example 2-4 | | | | | | | | | | | | | | |
| Synthesis | A-5 | a-5 | 100 | — | — | — | — | — | — | — | — | — | 5 | 2200 |
| Example 2-5 | | | | | | | | | | | | | | |
| Synthesis | A-6 | a-6 | 100 | — | — | — | — | — | — | — | — | — | 5 | 1800 |
| Example 2-6 | | | | | | | | | | | | | | |
| Synthesis | A-7 | a-7 | 100 | — | — | — | — | — | — | — | — | — | 5 | 1800 |
| Example 2-7 | | | | | | | | | | | | | | |
| Synthesis | A-8 | a-8 | 100 | — | — | — | — | — | — | — | — | — | 5 | 1700 |
| Example 2-8 | | | | | | | | | | | | | | |
| Synthesis | A-9 | a-9 | 100 | — | — | — | — | — | — | — | — | — | 5 | 1800 |
| Example 2-9 | | | | | | | | | | | | | | |
| Synthesis | A-10 | a-10 | 100 | — | — | — | — | — | — | — | — | — | 5 | 1700 |
| Example 2-10 | | | | | | | | | | | | | | |
| Synthesis | A-11 | a-11 | 100 | — | — | — | — | — | — | — | — | — | 5 | 1700 |
| Example 2-11 | | | | | | | | | | | | | | |
| Synthesis | A-12 | a-12 | 100 | — | — | — | — | — | — | — | — | — | 5 | 1700 |
| Example 2-12 | | | | | | | | | | | | | | |
| Synthesis | A-13 | a-1 | 90 | — | — | — | — | — | — | — | — | 10 | 5 | 2100 |
| Example 2-13 | | | | | | | | | | | | | | |
| Synthesis | A-14 | a-1 | 50 | 50 | — | — | — | — | — | — | — | — | 5 | 2100 |
| Example 2-14 | | | | | | | | | | | | | | |
| Synthesis | A-15 | — | — | 100 | — | — | — | — | — | — | — | — | 5 | 2500 |
| Example 2-15 | | | | | | | | | | | | | | |
| Synthesis | A-16 | — | — | 90 | — | — | — | — | — | — | — | 10 | 5 | 1900 |
| Example 2-16 | | | | | | | | | | | | | | |
| Synthesis | A-17 | — | — | 70 | — | — | — | — | — | — | — | 30 | 5 | 2000 |
| Example 2-17 | | | | | | | | | | | | | | |
| Synthesis | A-18 | — | — | 50 | — | — | — | — | — | — | — | 50 | 5 | 2100 |
| Example 2-18 | | | | | | | | | | | | | | |
| Synthesis | A-19 | — | — | — | 90 | — | — | — | — | — | — | 10 | 5 | 1800 |
| Example 2-19 | | | | | | | | | | | | | | |
| Synthesis | A-20 | — | — | — | — | 90 | — | — | — | — | — | 10 | 5 | 1800 |
| Example 2-20 | | | | | | | | | | | | | | |
| Synthesis | A-21 | — | — | — | — | — | 90 | — | — | — | — | 10 | 5 | 1800 |
| Example 2-21 | | | | | | | | | | | | | | |
| Synthesis | A-22 | — | — | — | — | — | — | 90 | — | — | — | 10 | 5 | 1700 |
| Example 2-22 | | | | | | | | | | | | | | |
| Synthesis | A-23 | — | — | — | — | — | — | — | 90 | — | — | 10 | 5 | 1800 |
| Example 2-23 | | | | | | | | | | | | | | |
| Synthesis | A-24 | — | — | — | — | — | — | — | — | 90 | — | 10 | 5 | 1700 |
| Example 2-24 | | | | | | | | | | | | | | |
| Synthesis | A-25 | — | — | — | — | — | — | — | — | — | 90 | 10 | 5 | 1700 |
| Example 2-25 | | | | | | | | | | | | | | |
| Synthesis | A-26 | — | — | 50 | — | 50 | — | — | — | — | — | — | 5 | 1700 |
| Example 2-26 | | | | | | | | | | | | | | |
| Synthesis | AJ-1 | a-13 | 100 | — | — | — | — | — | — | — | — | — | 5 | 2100 |
| Example 2-27 | | | | | | | | | | | | | | |
| Synthesis | AJ-2 | a-1 | 45 | — | — | — | — | — | — | — | — | 55 | 5 | 2000 |
| Example 2-28 | | | | | | | | | | | | | | |
| Synthesis | AJ-3 | — | — | 45 | — | — | — | — | — | — | — | 55 | 5 | 2300 |
| Example 2-29 | | | | | | | | | | | | | | |

### <Preparation of Underlayer Film-Forming Composition for Metal-Containing Resist>

The components used for preparing the underlayer film-forming composition for a metal-containing resist are shown below. In the following Examples 1-1 to 1-32 and Comparative Examples 1-1 to 1-3, unless otherwise specified, part by mass represents a value taken when the total mass of components used is 100 parts by mass.

[Compound [A] (including Comparative Examples)]
A-1 to A-26: Compounds (A-1) to (A-26) synthesized above
AJ-1 to AJ-3: Compounds (AJ-1) to (AJ-3) synthesized above for Comparative Examples

### [Solvent [B]]

B-1: Propylene glycol monomethyl ether acetate
B-2: Propylene glycol monomethyl ether

### [Other Optional Component [C]]

C-1 (Ortho ester): Trimethyl orthoformate
C-2 (Acid generator): Compound represented by formula (C-2) (in the formula, “Bu” represents a n-butyl group)
C-3 (Basic compound): Compound represented by formula (C-3)

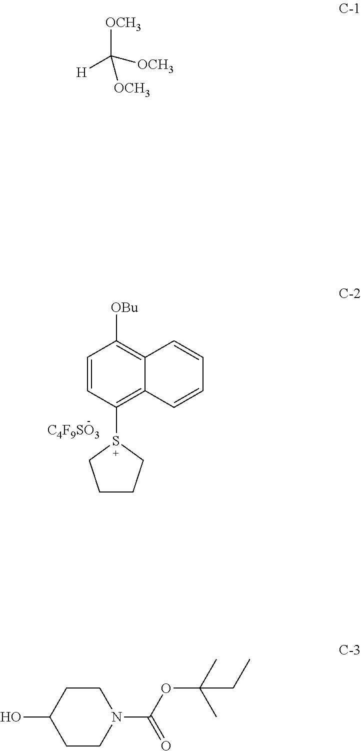

### [Example 1-1] (Preparation of Composition (J-1))

A silicon-containing composition (J-1) was prepared by mixing 0.50 parts by mass of (A-1) (excluding the solvent) as the compound [A] and 99.50 parts by mass of (B-1) (including the solvent (B-1) contained in the solution of the compound [A]) as the solvent [B], and filtering the resulting solution through a polytetrafluoroethylene (PTFE) membrane filter having a pore size of 0.2 μm.

### [Examples 1-2 to 1-32, Comparative Examples 1-1 to 1-3] (Preparation of Compositions (J-2) to (J-32) and (j-1) to (j-3))

Compositions (J-2) to (J-32) of Examples 1-2 to 1-32 and compositions (j-1) to (j-3) of Comparative Examples 1-1 to 1-3 were prepared in the same manner as in Example 1-1 except that respective components of types and blending amounts shown in the following Table 3 were used. “-” in the following Table 3 indicates that the corresponding component was not used.

### <Evaluation>

Using the underlayer film-forming composition for a metal-containing resist prepared as described above, the rectangularity of a resist pattern was evaluated by the following method. The evaluation results are shown in the following Table 3.

### <Preparation of Resist Composition (R-1)>

### [Synthesis of Metal-Containing Compound]

The compound (S-1) as the metal-containing compound to be used for the preparation of the resist composition (R-1) was synthesized by the following procedure. Into a reaction vessel, 6.5 parts by mass of isopropyltin trichloride were added while stirring 150 mL of a 0.5 N aqueous sodium hydroxide solution, and stirring was carried out for 2 hours. The precipitate formed was collected by filtration, washed twice with 50 parts by mass of water, and then dried to obtain a compound (S-1). The compound (S-1) was an oxidized hydroxide product of a hydrolysate of isopropyltin trichloride (the oxidized hydroxide product contained i-PrSnO_{(3/2-x/2)}(OH)ₓ (0<x<3) as a structural unit).

Mixed were 2 parts by mass of the compound (S-1) synthesized above and 98 parts by mass of propylene glycol monoethyl ether, and the obtained mixture was subjected to removal of residual water with activated 4 Å molecular sieve, and then filtered through a polytetrafluoroethylene (PTFE) membrane filter having a pore size of 0.2 μm. Thus, a resist composition (R-1) was prepared.

### [Resist Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Limited), and thereafter heating was conducted at 250° C. for 60 sec to form an organic underlayer film having an average thickness of 100 nm. To the organic underlayer film was applied the underlayer film-forming composition for a metal-containing resist prepared above, heated at 220° C. for 60 seconds, and then cooled at 23° C. for 30 seconds. Thus, an underlayer film for a metal-containing resist having an average thickness of 5 nm was formed. The underlayer film for a metal-containing resist was coated with the resist composition (R-1) by the spin coating method using a spin coater described above, and after a lapse of a prescribed time, heated at 90° C. for 60 seconds, and then cooled at 23° C. for 30 seconds. Thus, a resist film having an average thickness of 35 nm was formed.

The resist film was exposed to light using an EUV scanner (“TWINSCAN NXE: 3300B”, available from ASML Co. (NA=0.3; Sigma=0.9; quadrupole illumination, with a 1:1 line and space mask having a line width of 25 nm in terms of a dimension on wafer)). After the exposure, the substrate was heated at 110° C. for 60 seconds, and subsequently cooled at 23° C. for 60 seconds. Thereafter, development was performed by a paddle method using Dev-1:2-heptanone (20 to 25° C.) or Dev-2: propylene glycol monomethyl ether acetate (20 to 25° C.) as a developer, and drying was then performed to obtain a substrate for evaluation on which a resist pattern was formed. A scanning electron microscope (“SU8220” available from Hitachi High-Tech Corporation) was used for length measurement and observation of the resist pattern of the substrate for evaluation. The pattern rectangularity was evaluated as “A” (good) when the cross-sectional shape of the pattern was rectangular, “B” (slightly good) when trailing was present in the cross-sectional shape of the pattern, and “C” (poor) when a residue (defect) was present in the pattern.

TABLE 3

| | Underlayer | | | | | Other optional | | | |
|---|---|---|---|---|---|---|---|---|---|
| | film-forming | Compound [A] | | Solvent [B] | | component [C] | | | |
| | composition | | Blending | | Blending | | Blending | Resist pattern | Resist pattern |
| | for metal- | | amount | | amount | | amount | rectangularity | rectangularity |
| | containing | | (parts by | | (parts by | | (parts by | Developer: | Developer: |
| | resist | Type | mass) | Type | mass) | Type | mass) | Dev-1 | Dev-2 |
| Example | J-1 | A-1 | 0.50 | B-1 | 99.50 | — | — | A | A |
| 1-1 | | | | | | | | | |
| Example | J-2 | A-2 | 0.50 | B-1 | 99.50 | — | — | A | A |
| 1-2 | | | | | | | | | |
| Example | J-3 | A-2 | 0.50 | B-1 | 96.50 | C-1 | 3.00 | A | A |
| 1-3 | | | | | | | | | |
| Example | J-4 | A-2 | 0.50 | B-1 | 99.47 | C-2 | 0.03 | A | A |
| 1-4 | | | | | | | | | |
| Example | J-5 | A-2 | 0.50 | B-1 | 99.47 | C-3 | 0.03 | A | A |
| 1-5 | | | | | | | | | |
| Example | J-6 | A-3 | 0.50 | B-1 | 99.50 | — | — | A | A |
| 1-6 | | | | | | | | | |
| Example | J-7 | A-4 | 0.50 | B-1 | 99.50 | — | — | B | B |
| 1-7 | | | | | | | | | |
| Example | J-8 | A-5 | 0.50 | B-1 | 99.50 | — | — | A | A |
| 1-8 | | | | | | | | | |
| Example | J-9 | A-6 | 0.50 | B-1 | 99.50 | — | — | A | A |
| 1-9 | | | | | | | | | |
| Example | J-10 | A-7 | 0.50 | B-1 | 99.50 | — | — | A | A |
| 1-10 | | | | | | | | | |
| Example | J-11 | A-8 | 0.50 | B-1 | 99.50 | — | — | A | A |
| 1-11 | | | | | | | | | |
| Example | J-12 | A-9 | 0.50 | B-1 | 99.50 | — | — | A | A |
| 1-12 | | | | | | | | | |
| Example | J-13 | A-10 | 0.50 | B-1 | 99.50 | — | — | A | A |
| 1-13 | | | | | | | | | |
| Example | J-14 | A-11 | 0.50 | B-1 | 99.50 | — | — | A | A |
| 1-14 | | | | | | | | | |
| Example | J-15 | A-12 | 0.50 | B-1 | 99.50 | — | — | A | A |
| 1-15 | | | | | | | | | |
| Example | J-16 | A-13 | 0.50 | B-1 | 99.50 | — | — | A | A |
| 1-16 | | | | | | | | | |
| Example | J-17 | A-14 | 0.50 | B-1 | 99.50 | — | — | A | A |
| 1-17 | | | | | | | | | |
| Example | J-18 | A-15 | 0.50 | B-1/B-2 | 29.85/69.65 | — | — | A | A |
| 1-18 | | | | | | | | | |
| Example | J-19 | A-16 | 0.50 | B-1/B-2 | 29.85/69.65 | — | — | A | A |
| 1-19 | | | | | | | | | |
| Example | J-20 | A-16 | 0.50 | B-1/B-2 | 28.95/67.55 | C-1 | 3.00 | A | A |
| 1-20 | | | | | | | | | |
| Example | J-21 | A-16 | 0.50 | B-1/B-2 | 29.84/69.63 | C-2 | 0.03 | A | A |
| 1-21 | | | | | | | | | |
| Example | J-22 | A-16 | 0.50 | B-1/B-2 | 29.84/69.63 | C-3 | 0.03 | A | A |
| 1-22 | | | | | | | | | |
| Example | J-23 | A-17 | 0.50 | B-1/B-2 | 29.85/69.65 | — | — | A | A |
| 1-23 | | | | | | | | | |
| Example | J-24 | A-18 | 0.50 | B-1/B-2 | 29.85/69.65 | — | — | B | B |
| 1-24 | | | | | | | | | |
| Example | J-25 | A-19 | 0.50 | B-1/B-2 | 29.85/69.65 | — | — | A | A |
| 1-25 | | | | | | | | | |
| Example | J-26 | A-20 | 0.50 | B-1/B-2 | 29.85/69.65 | — | — | A | A |
| 1-26 | | | | | | | | | |
| Example | J-27 | A-21 | 0.50 | B-1/B-2 | 29.85/69.65 | — | — | A | A |
| 1-27 | | | | | | | | | |
| Example | J-28 | A-22 | 0.50 | B-1/B-2 | 29.85/69.65 | — | — | A | A |
| 1-28 | | | | | | | | | |
| Example | J-29 | A-23 | 0.50 | B-1/B-2 | 29.85/69.65 | — | — | A | A |
| 1-29 | | | | | | | | | |
| Example | J-30 | A-24 | 0.50 | B-1/B-2 | 29.85/69.65 | — | — | A | A |
| 1-30 | | | | | | | | | |
| Example | J-31 | A-25 | 0.50 | B-1/B-2 | 29.85/69.65 | — | — | A | A |
| 1-31 | | | | | | | | | |
| Example | J-32 | A-26 | 0.50 | B-1/B-2 | 29.85/69.65 | — | — | A | A |
| 1-32 | | | | | | | | | |
| Comparative | j-1 | AJ-1 | 0.50 | B-1 | 99.50 | — | — | C | C |
| Example 1-1 | | | | | | | | | |
| Comparative | j-2 | AJ-2 | 0.50 | B-1 | 99.50 | — | — | C | C |
| Example 1-2 | | | | | | | | | |
| Comparative | j-3 | AJ-3 | 0.50 | B-1/B-2 | 29.85/69.65 | — | — | C | C |
| Example 1-3 | | | | | | | | | |

As is apparent from the results in Table 3, the underlayer films for a metal-containing resist formed from the compositions of Examples successfully exhibited excellent pattern rectangularity as compared with the underlayer films for a metal-containing resist formed from the compositions of Comparative Examples.

The method for manufacturing a semiconductor substrate and the underlayer film-forming composition for a metal-containing resist according to the present disclosure can form an underlayer film for a metal-containing resist with excellent pattern rectangularity. Therefore, these can be suitably used for manufacturing the semiconductor substrate and the like.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, the method comprising:
applying an underlayer film-forming composition directly or indirectly to a substrate to form an underlayer film;
applying a composition for forming a metal-containing resist film to the underlayer film to form a metal-containing resist film;
exposing the metal-containing resist film to extreme ultraviolet rays; and
developing the exposed metal-containing resist film, wherein the underlayer film-forming composition comprises:
a compound comprising at least one structural unit selected from the group consisting of a structural unit (α-1) represented by formula (1-1) and a structural unit (α-2) represented by formula (1-2); and
a solvent, and
a total content ratio of the structural unit (α-1) and the structural unit (α-2) to all structural units constituting the compound is 50 mol % or more and 100 mol % or less: 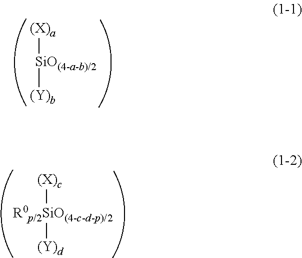
wherein,
in the formula (1-1), X is a monovalent aliphatic hydrocarbon group having 1 to 20 carbon atoms or a monovalent aliphatic hydrocarbon group having 1 to 20 carbon atoms substituted with at least one halogen atom; a is an integer of 1 to 3; when a is 2 or more, the plurality of Xs are the same or different from each other; Y is a monovalent organic group having 1 to 20 carbon atoms, a hydroxy group, or a halogen atom; b is an integer of 0 to 2; when b is 2, two Ys are the same or different from each other; and a+b is 3 or less,
in the formula (1-2), X is a monovalent aliphatic hydrocarbon group having 1 to 20 carbon atoms or a monovalent aliphatic hydrocarbon group having 1 to 20 carbon atoms substituted with at least one halogen atom; c is an integer of 1 to 3; when c is 2 or more, the plurality of Xs are the same or different from each other; Y is a monovalent organic group having 1 to 20 carbon atoms, a hydroxy group, or a halogen atom; d is an integer of 0 to 2; when d is 2, two Ys are the same or different from each other; R⁰ is a substituted or unsubstituted divalent hydrocarbon group that has 1 to 20 carbon atoms and is bonded to two silicon atoms; p is an integer of 1 to 3; when p is 2 or more, the plurality of Ros are the same or different from each other; and c+d+p is 4 or less.

2. The method for manufacturing a semiconductor substrate according to claim 1, wherein the underlayer film has a film thickness of 6 nm or less.

3. The method for manufacturing a semiconductor substrate according to claim 1, wherein a total content ratio of the structural unit (α-1) and the structural unit (α-2) to all structural units constituting the compound is 60 mol % or more and 100 mol % or less.

4. The method for manufacturing a semiconductor substrate according to claim 1, wherein the composition for forming a metal-containing resist film comprises: a metal-containing compound; and a solvent, and a content ratio of the metal-containing compound to components other than the solvent in the composition for forming a metal-containing resist film is 50% by mass or more.

5. The method for manufacturing a semiconductor substrate according to claim 1, wherein developing comprises developing the exposed metal-containing resist film with an organic solvent.

6. An underlayer film-forming composition, comprising:
a compound comprising at least one structural unit selected from the group consisting of a structural unit (α-1) represented by formula (1-1) and a structural unit (α-2) represented by formula (1-2); and
a solvent, wherein
a total content ratio of the structural unit (α-1) and the structural unit (α-2) to all structural units constituting the compound is 50 mol % or more and 100 mol % or less: 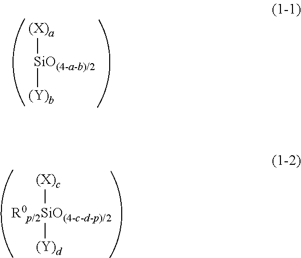
wherein
in the formula (1-1), X is a monovalent aliphatic hydrocarbon group having 1 to 20 carbon atoms or a monovalent aliphatic hydrocarbon group having 1 to 20 carbon atoms substituted with at least one halogen atom; a is an integer of 1 to 3; when a is 2 or more, the plurality of Xs are the same or different from each other; Y is a monovalent organic group having 1 to 20 carbon atoms, a hydroxy group, or a halogen atom; b is an integer of 0 to 2; when b is 2, two Ys are the same or different from each other; and a+b is 3 or less,
in the formula (1-2), X is a monovalent aliphatic hydrocarbon group having 1 to 20 carbon atoms or a monovalent aliphatic hydrocarbon group having 1 to 20 carbon atoms substituted with at least one halogen atom; c is an integer of 1 to 3; when c is 2 or more, the plurality of Xs are the same or different from each other; Y is a monovalent organic group having 1 to 20 carbon atoms, a hydroxy group, or a halogen atom; d is an integer of 0 to 2; when d is 2, two Ys are the same or different from each other; R⁰ is a substituted or unsubstituted divalent hydrocarbon group that has 1 to 20 carbon atoms and is bonded to two silicon atoms; p is an integer of 1 to 3; when p is 2 or more, the plurality of Ros are the same or different from each other; and c+d+p is 4 or less.

7. The underlayer film-forming composition according to claim 6, which is suitable for forming an underlayer film having a film thickness of 6 nm or less.

8. The underlayer film-forming composition according to claim 6, wherein a total content ratio of the structural unit (α-1) and the structural unit (α-2) to all structural units constituting the compound is 60 mol % or more and 100 mol % or less.

9. The underlayer film-forming composition according to claim 6, wherein, in the formula (1-1) and the formula (1-2), X is a monovalent chain aliphatic saturated hydrocarbon group having 1 to 5 carbon atoms or a monovalent alicyclic saturated hydrocarbon group having 3 to 6 carbon atoms.

10. The underlayer film-forming composition according to claim 6, wherein the composition for forming a metal-containing resist film comprises: a metal-containing compound; and a solvent, and a content ratio of the metal-containing compound to components other than the solvent in the composition for forming a metal-containing resist film is 50% by mass or more.
